(19) United States
(12) Patent Application Publication
(10) Pub. No.: US 2013/0013975 A1
(43) Pub. Date: Jan. 10, 2013

(54) SYSTEM AND DEVICE

(76) Inventor: Kenta YASUFUKU, Kawasaki-shi (JP)

(21) Appl. No.: 13/542,099

(22) Filed: Jul. 5, 2012

(30) Foreign Application Priority Data
Jul. 5, 2011 (JP) 2011-149379

(51) Int. Cl. H03M 13/05; G06F 11/10; H03M 13/29

(52) U.S. Cl. 714/758; 714/776; 714/E11.032

(57) ABSTRACT

According to one embodiment, a system includes a plurality of ring-connected devices. The system includes a first device and a second device. The second device is connected to receive a signal from the first device. When the first device is a data relay station and receives the data containing an error, the first device replaces a part of the data with internally generated data and transmits the resultant data to the second device.

### CROSS-REFERENCE TO RELATED APPLICATIONS

This application is based upon and claims the benefit of priority from prior Japanese Patent Application No. 2011-149379, filed Jul. 5, 2011, the entire contents of which are incorporated herein by reference.

### FIELD

Embodiments described herein relate generally to a system and device.

### BACKGROUND

In recent years, the capacities of data storage devices such as SD cards (registered trademark) have been significantly increased, the definition of images has been significantly increased by the improved resolutions of digital cameras and the like, and image quality has been markedly enhanced by the increased frame rate of image data. Under these circumstances, the amount of data transmitted between a host apparatus and a storage device in which data is recorded has been steadily increasing. A high-speed serial transmission scheme based on small-amplitude differential signals is now commonly used for such large-capacity data transmission in order to, for example, simplify connection cables, suppress power consumption, and reduce EMI emission noise. Such a high-speed serial transmission scheme also commonly uses coding such as 8b/10b in order to stabilize the transmission.

### BRIEF DESCRIPTION OF THE DRAWINGS

FIG. 1 is a block diagram showing a system (ring topology) according to a referential example;

FIG. 2 and FIG. 3 are flowcharts showing how data burst streaming is enabled and disabled, respectively, according to the referential example;

FIG. 4 is a block diagram showing a loopback path according to the referential example;

FIG. 5 is a block diagram showing a configuration example of a transceiver device (device 0);

FIG. 6, FIG. 7, and FIG. 8 are diagrams showing that error information is generated according to a first embodiment;

FIG. 9 is a flowchart showing how error detection and transmission are carried out on the error information according to the first embodiment;

FIG. 10 is a diagram showing K-symbols according to a second embodiment;

FIG. 11 is a diagram showing how error information is transmitted according to the second embodiment;

FIG. 12 is a flowchart showing how error detection and transmission are carried out on the error information is detected according to the second embodiment;

FIG. 13 is a diagram showing how error information is transmitted according to a third embodiment;

FIG. 14 is a flowchart showing how error detection and transmission are carried out on the error information according to the third embodiment;

FIG. 15 is a diagram showing how error information is transmitted according to a fourth embodiment; and

FIG. 16 is a flowchart showing how error detection and transmission are carried out on the error information according to the fourth embodiment.

### DETAILED DESCRIPTION

In general, according to one embodiment, a system includes a plurality of ring-connected devices. The system includes a first device and a second device. The second device is connected to receive a signal from the first device. When the first device is a data relay station and receives the data containing an error, the first device replaces a part of the data with internally generated data and transmits the resultant data to the second device.

### Referential Example

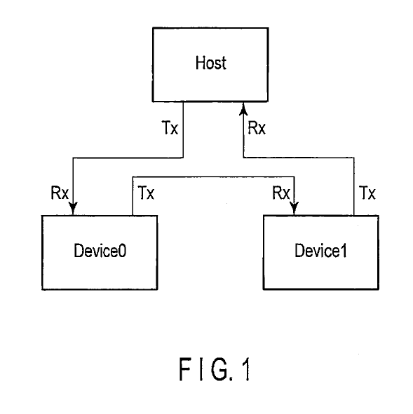

First, the referential example will be described with reference to FIG. 1 to FIG. 4.

<System (Ring Topology)>

First, a system (ring topology) will be described with reference to FIG. 1.

As shown in FIG. 1, the system in the present example includes a host and two transceiver (transmitter/receiver) devices (device 0 and device 1). A transmission terminal of the host is connected to a reception terminal of the transceiver device (device 0). A transmission terminal of the transceiver device (device 0) is connected to a reception terminal of the transceiver device (device 1). A transmission terminal of the transceiver device (device 1) is connected to a reception terminal of the host. In this manner, the transmission terminal of each node is connected to the reception terminal of the succeeding node. Thus, such a system is referred to as a ring topology because the connected nodes form a ring.

The ring topology in the present example complies with, for example, the UHS-II standard developed by SD Association. Thus, the ring topology is considered to be a connection form for connecting a plurality of devices together.

In this case, in the ring topology conforming to the UHS-II standard, a header is stored in each packet transmitted and received between the nodes. Upon receiving a packet, a device compares a destination ID (DID) held in the header with the ID of the device (OWN_NODE_ID) to determine whether the packet is destined for the device or another station.

However, for example, according to the UHS-II standard, when a packet is received, whether an error has occurred in the contents of the packet needs to be determined using cyclic redundancy checks (CRCs). That is, all of the data is temporarily received, and only if a CRC value embedded in the packet is equal to that calculated utilizing the received data, indicating that no error has occurred, the contents of the packet can be checked to determine the destination. Thus, data packets with relatively large data sizes (512 bytes or the like) tend to require much time for relaying when the packets are destined for another station.

Thus, for data burst transfer in which data packets are transferred, the UHS-II standard utilizes a mechanism called data burst streaming which reduces the time required for relaying the packets.

<Flow of Enabling Data Burst Streaming>

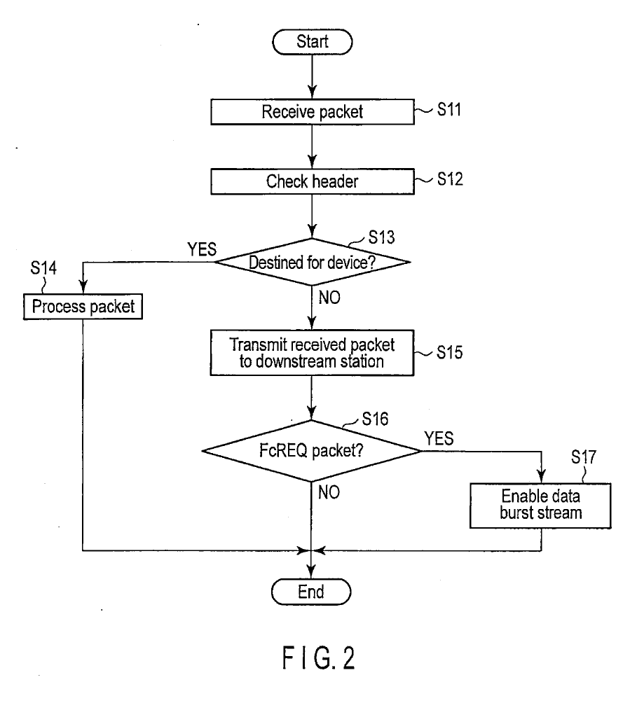

A flow of enabling data burst streaming will be described in accordance with FIG. 2. Here, an example is taken in which in the ring topology, an upstream device (device 0), upon receiving a packet transmitted by a host, transfers the packet to a downstream device (device 1). The control of the flow described below is performed by, for example, controllers in the devices (device 0 and device 1).

First, in step S11, the upstream device (device 0) receives the packet from the host.

Subsequently, in step S12, device 0 checks the header of the received packet.

Subsequently, in step S13, device 0 determines whether or not the packet is destined for device 0 based on the contents of the header.

Subsequently, if in step S13, device 0 determines that the packet is destined for device 0 (Yes), then in step S14, device 0 processes the packet and ends the flow (End).

If in step S13, device 0 determines that the packet is not destined for device 0 (No), then in step S15, device 0 transmits the received packet to the downstream device (in the present example, device 1).

Subsequently, in step S16, device 0 determines whether or not the received packet is a flow control request packet (FCREQ packet) (No). If device 0 determines that the received packet is not a flow control request packet (No), device 0 ends the flow.

If in step S16, device 0 determines that the received packet is a flow control request packet (Yes), then in step S17, device 0 enables data burst streaming and ends the flow (End).

As described above, in the data burst streaming flow, the burst transfer is enabled utilizing the flow control request (FCREQ) packet used for flow control performed before the burst transfer (S17). Thus, when the upstream device (device 0) relays a packet to the downstream device (device 1), if the packet is an FCREQ packet, device 0 can determine that a data burst transfer to the succeeding downstream device (device 1) will occur. At this time, for packets in the subsequent data burst to the downstream device (device 1), checks on the headers and the like are not carried out, and transmitted data is relayed directly to the downstream device without buffering. This enables a reduction in the time required to relay the packets.

Furthermore, the data burst streaming is disabled when a specific control code that is transferred at the end of the data burst (for example, End of Data Burst [EDB]) is relayed. Now, the flow of this operation will be illustrated.

<Flow of Disabling the Data Burst Streaming>

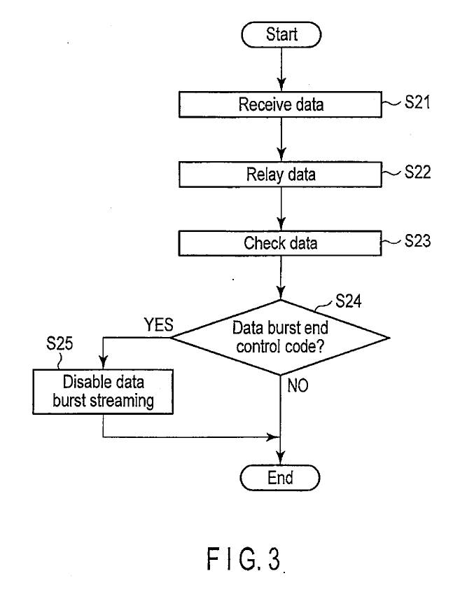

A flow of disabling the data burst streaming will be described in accordance with FIG. 3. In this case, an example is taken in which during data relay in the ring topology, the upstream device (device 0) transmits a packet to the downstream device (device 1) with the data burst streaming enabled. The control of the flow described below is similarly performed, for example, by the controllers in the devices (device 0 and device 1) only while the data burst streaming is enabled.

First, in step S21, the upstream device (device 0) receives the packet data transmitted by the host.

Subsequently, in step S22, since the data burst streaming is enabled, the upstream device (device 0) relays and transmits the received packet to the downstream device (device 1).

Subsequently, in step S23, the upstream device (device 0) checks the relayed data.

Subsequently, in step S24, the upstream device (device 0) determines whether or not the relayed data contains an end control code (End of Data Burst [EDB]). If the upstream device determines that the relayed data does not contain the end control code (EDB) (No), the upstream device ends the flow (End).

If in step S24, the upstream device determines that the data contains the end control code (EDB) (Yes), the upstream device disables the data burst streaming and ends the flow (End).

<Loopback Path>

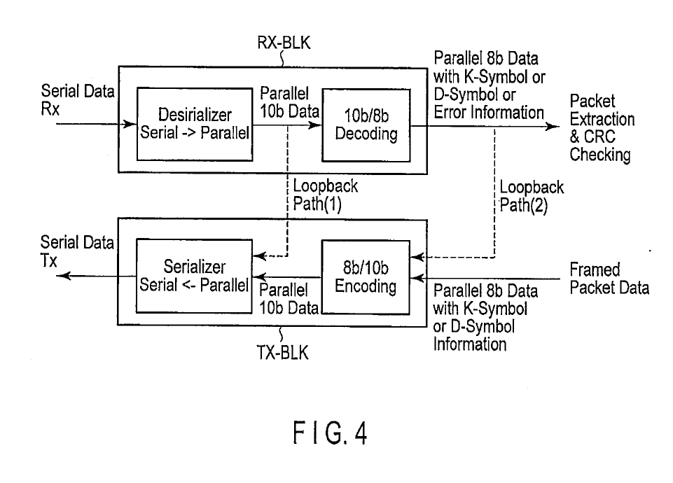

Now, a loopback path through which the “coming data is relayed directly to the downstream device” will be described with reference to FIG. 4. FIG. 4 is a block diagram of a partial area of device 0, device 1, or the host shown in FIG. 1. In particular, FIG. 4 shows a receiver circuit block RX-BLK and a transmitter circuit block TX-BLK of device 0, device 1, or the host.

As shown in FIG. 4, device 0, device 1, and the host include the loopback path through which signals are passed from the receiver circuit block RX-BLK to the transmitter circuit block TX-BLK. Two types of the loop back path are presented: a loopback path(1) through which data received at a deserializer is transmitted and a loopback path(2) through which data received at a 10b8b decoding block is transmitted.

In FIG. 4, blocks labeled as “8b10b encoding” and “10b8b decoding” perform encoding and decoding, respectively, based on a 8b10b encoding scheme. The 8b10b encoding scheme expresses 8-bit data in 10 bits to allow a control code to be embedded in the data. This scheme is adopted for many standards, for example, Ethernet (registered trademark), Fibre Channel, IEEE 1394, PCI Express 2.0, Serial ATA, and USB 3.0.

A serializer converts data with a 10-bit width into data with 1-bit width and a tenfold speed (serialization). In contrast, the deserializer converts data with a 1-bit width into data with a 10-bit width and a one-tenth speed (deserialization). The 8b10b encoder, 10b8b decoder, serializer, and deserializer are implemented by, for example, the controllers in the required devices (device 0 and device 1), which will be described below.

Of the two types of methods described above, the one with the loopback path (1) involves a shorter latency for data relay than the one with the loopback path(2) but requires special processing for holding running disparity that is characteristic of the 8b10b encoding scheme. Thus, the loopback path(2) in which the data output from the 10b8b decoding block is transmitted to the serializer is easier in terms of implementation and preferable. However, the method with the loopback path(2) has the following tendency.

In this case, according to the UHS-II standard, received data is checked for errors in the following two steps.

1. During the 10b8b decoding, the device determines whether or not 10-bit data is present in a conversion table.

2. After extracting a packet from 8-bit data, the device uses CRC to validate the packet.

Thus, double-checking is carried out using the 10b8b decoding and CRC.

However, problems may result from the following possible situations in the configuration shown in FIG. 1.

(I) Host transmits a data packet destined for device 1.

(II) Subsequently, in this case, device 0 serves as a relay station and thus relays the data packet by the method with the loopback path(2).

(III) Noise occurs in the path between the host and device 0 to preclude the data from being subjected to the 10b8b decoding, resulting in garbled data.

In this case, if the destination of the data is device 0, no relay station is present and device 0 can thus detect an error during the 10b8b decoding. The data packet can be determined to be invalid regardless of the result of CRC. However, in the above-described example, device 0 serves as a relay station and thus needs to retransmit the erroneous 8-bit data to device 1. This is because the 8b10b encoding involves no mechanism or function for transmitting error information, causing the 10-bit data with no error information to be transmitted to device 1.

Thus, device 1, which has not received the error information, ends the 10b8b encoding normally and validates the packet using only CRC. CRC is like a signature for the entire data, and thus completely different data may accidentally have an equal CRC value, though the possibility is very slim. Hence, if the 10b8b decoding fails to detect the error, the originally erroneous data is likely to be mistakenly determined to be correct. If the error part of the transmitted data fails to be recognized, the downstream device (device 1) may mistakenly determine the data to be correct even though the error is actually occurring in the data. As a result, the data may be corrupted.

Thus, based on the knowledge obtained from the referential example, the following embodiment can prevent receive data from being mistakenly received as described above. How the upstream device serving as a relay station transmits the error information detected during the 10b8b decoding to the succeeding downstream device to notice the downstream device of the error will be described with reference to the drawings. In this description, common components are denoted by common reference numbers throughout the drawings.

### First Embodiment

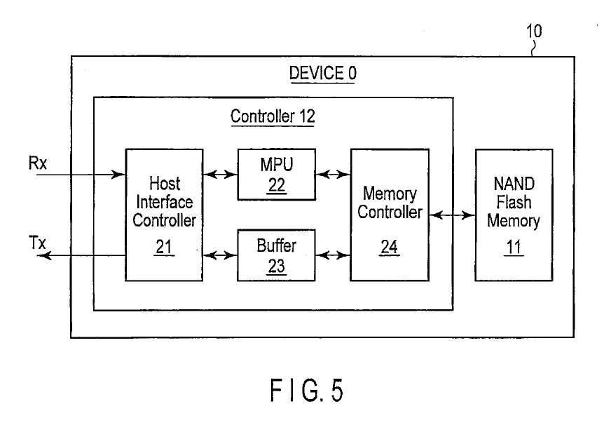

Now, a first embodiment will be described with reference to FIG. 5 to FIG. 9. Detailed descriptions overlapping those given above are omitted.

<1. Configuration Example of the Transceiver Device (Device 0)>

First, a configuration example of a transceiver device according to the first embodiment (in the present example, a semiconductor storage device) will be described with reference to FIG. 5. Here, one transceiver device (device 0) arranged in a system (ring topology) complying with the UHS-II standard is taken as an example.

Here, the illustrated device 0 is, for example, device represented by an SD card (registered trademark) and in which a NAND flash memory 11 is embedded. However, device 0 is not limited to the memory device configuration illustrated herein. In connection with a technique related to a host interface controller 21 in a memory controller 12 described below, the present example is applicable to, for example, a transceiver device such as a wireless LAN card with a wireless LAN interface mounted therein instead of the memory controller 12 and the NAND flash memory 11.

As shown in FIG. 5, the device (device 0) in the present example includes a NAND flash memory 11 and a controller 12 that controls the NAND flash memory 11.

The NAND flash memory 11 stores data in a memory cell array in a nonvolatile manner; the memory cell array includes a plurality of memory cells arranged in a matrix at positions where word lines and bit lines intersect one another. Each of the memory cells includes a tunnel insulating film, a charge accumulation layer, an inter-electrode insulating film, and a control gate sequentially stacked on a semiconductor substrate. The control gate is connected to the word lines. A plurality of current paths through the memory cells are connected together in the direction of the bit lines to form a memory cell unit.

Furthermore, data is written and read in units of word lines (units of pages). For data erase, each block of data is erased at a time.

The controller 12 includes the host interface 21, MPU 22, a buffer 23, and a memory controller 24.

The host interface controller 21 performs predetermined data conversions for transmission and reception of command and data packets to and from a device external to the device to which the host interface controller 21 belongs (the external device may be the host or a device other than the device to which the host interface controller 21 belongs), for example, the 8b10b encoding, 10b8b decoding, serialization, and deserialization, and determines whether or not a received packet is destined for the device to which the host interface controller 21 belongs. The configuration described above with reference to FIG. 4 may be included in the host interface controller 21.

MPU 22 controls the whole controller 12. The above-described 8b10b encoding, 10b8b decoding, CRC addition process, CRC check process, and determination of the received packet destination may be carried out by MPU 22.

The buffer 23 expands and stores data and control programs from the host interface 21 and the memory controller 24.

The memory controller 24 is controlled by MPU and controls the NAND flash memory 11.

<2. Data Transfer Operation>

A data transfer operation performed in the above-described configuration will be described below.

2-1. Generation of Error Information

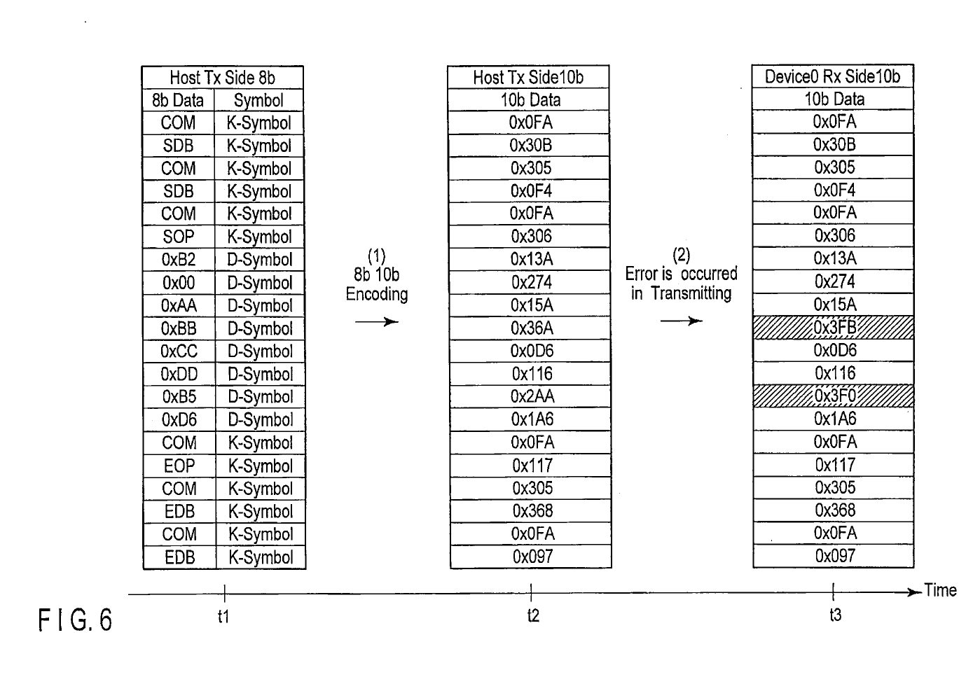

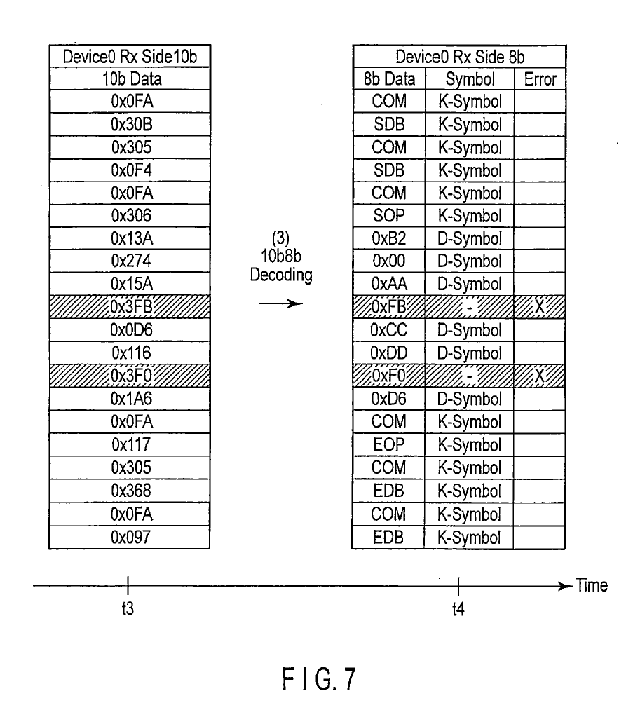

First, generation of error information during a data transfer operation will be described with reference to FIG. 6 to FIG. 8. Here, an example is taken in which in the memory system (ring topology) shown in FIG. 1 described above, device 0 serving as an upstream relay station transfers data transmitted by the host to the downstream device 1. Furthermore, operations described below are controlled by the controller 12. More specifically, if the 8b10b encoding, 10b8b decoding, CRC addition process, CRC check process, and the like are carried out by the host interface controller 21, the host controller 21 executes the following processing in accordance with instructions from MPU 21. Tables shown in FIG. 6 to FIG. 8 illustrate data strings obtained at the respective points of time and are shown in temporal order.

First, as shown at time t1 in FIG. 6, in order to transmit 8-bit data strings (host Tx side 8b) to the upstream device 0, the host carries out the 8b10b encoding (labeled with (1) in FIG. 6) on data (8b data) and symbol information (symbol) in each of the data strings to convert the 8-bit data string into a 10-bit data string (host Tx side 10b) shown at time t2.

In 8b10b coding, 8-bits data is converted to 10-bits data, that is, 8-bits patterns are associated with 10-bits patterns. In this association, any of 10-bits patterns are not associated with 8-bits data, in other words, there are remainder set of 10-bits pattern which is not associated with data. These remainder 10-bits patterns are associated with K-symbol for using as control codes. For example, the K-symbol used for the UHS-II standard will be described below in a second embodiment in detail.

Subsequently, the 10-bit data transmitted by the host passes through a transmission path and is thus transferred from the host to device 0. In actuality, the original bit string is converted into a 1-bit string by serialization on the transmission side, and the 1-bit string passes through the transmission path and is then converted into a 10-bit data string by deserialization on the reception side. However, for simplification, the description is based on the bits. The same applies to the example described below.

It is assumed that an error occurs (labeled with (2) in FIG. 6) during the data transmission to garble the values of 10-bit data strings, resulting in data strings shown at time t3 as “device 0 Rx side 10b” in FIG. 6. In the present example, an error occurs in shaded data shown at time t3 in FIG. 6, and the data 0x36A and 0x2AA are garbled into the data 0x3FB and 0x3F0.

Subsequently, as shown at times t3 to t4 in FIG. 7, device 0 converts the 10b data string into an 8b data string (device 0 Rx side 8b) by 10b8b decoding (labeled with (3) in FIG. 7). In this case, the erroneous parts 0x3FB and 0x3F0 are garbled into values that cannot be subjected to a 10b8b conversion. Thus, among the 8-bit data strings (device 0 Rx side 8b), the erroneous parts are expressed as the data 0xFB and 0xF0 with an error flag (error). Here, the value of the 8-bit data varies depending on the implementation, and the present embodiment extracts the lower 8 bits from the 10-bit data. Furthermore, because of the failure in decoding, symbol information is unknown.

In this case, when the erroneous 8-bit data strings (device 0 Rx side 8b) are transferred to the downstream device (device 1) without any change, the originally erroneous data 0xFB and 0xF0 may be mistakenly determined to be correct. This possibility increases, for example, if the errors cannot be detected during the 10b8b decoding.

As a result, the downstream device (device 1) accepts the erroneous data as correct data, resulting in corruption of the data.

2-2. Replacement of the Error Data

Thus, as shown at times t4 to t5 in FIG. 8, if errors are occurring, then during an 8b10b encoding & error injection process, device 0 replaces the erroneous parts 0xFB and 0xF0 with 0x010 (labeled with (4) in FIG. 8), a 10-bit pattern that is unused for the 8b10b encoding. The unused 10-bit pattern for replacing the erroneous parts may be selected from 10-bit patterns except for patterns associated with 8-bit data and patterns associated with K-symbol, and is not limited to 0x010. 10-bit patterns associated with 8-bit pattern or K-symbol are disclosed in U.S. patent application Ser. No. 06/394,045.

Then, the data strings (device 0 Tx 10b) resulting from the replacement are transmitted to the downstream device (device 1). Thus, the succeeding downstream device (device 1) can detect the errors during the 10b8b decoding or the like.

2-3. Flow of the Data Transfer Operation

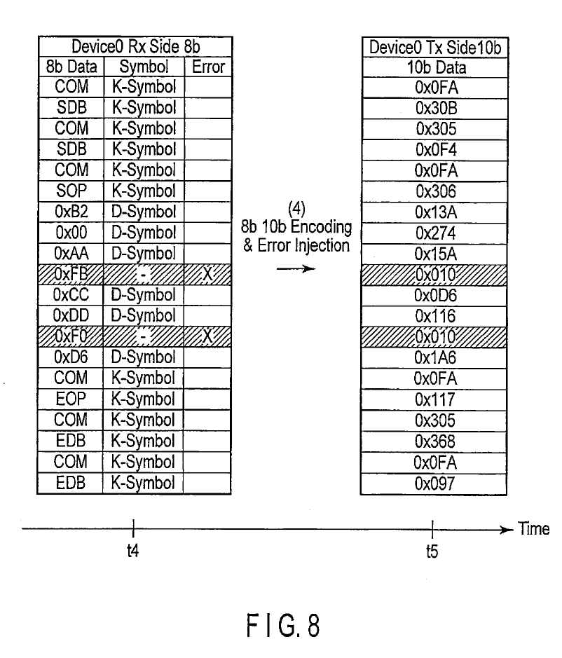

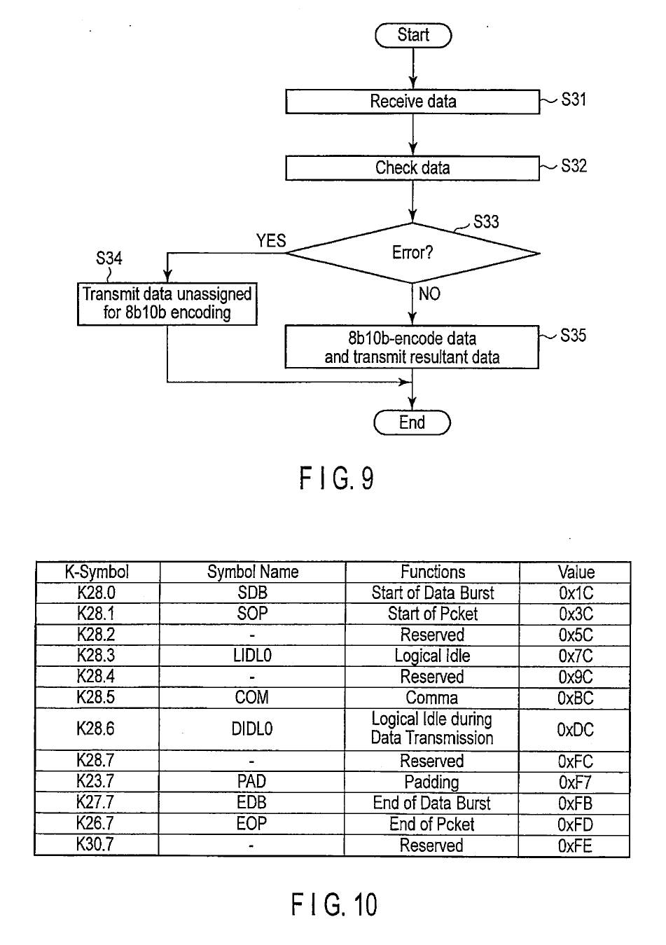

The above-described data transfer operation can be described in the form of an operation flow as shown in FIG. 9.

First, in step S31, the upstream device 0 receives packet data transmitted by the host. At this time, device 0 carries out, for example, the 10b8b decoding on the received data.

Subsequently, in step S32, device 0 checks the converted received data.

Subsequently, in step S33, device 0 determines whether or not any error is occurring in the received data. At this time, the controller 12 determines whether or not any error is occurring, for example, depending on whether or not the error flag is present. For example, as shown in FIG. 7 described above, the erroneous parts 0x3FB and 0x3F0 are garbled into values that cannot be subjected to a 10b8b conversion. Thus, among the 8-bit data strings (device 0 Rx side 8b), the erroneous parts are expressed as the data 0xFB and 0xF0 with the error flag.

Subsequently, if in step S33, device 0 determines that errors are occurring (Yes), then in step S34, device 0 replaces the data with one that is unassigned for the 8b10b encoding, and transmits the new data to the downstream device 1. Device 0 ends this flow (End).

For example, as shown in FIG. 8 described above, if errors are occurring, then during the 8b10b encoding & error injection process (labeled with (4) FIG. 8), device 0 replaces the erroneous parts 0xFB and 0xF0 with 0x010, an unregistered pattern. Thus, transmitting the data strings (device 0 Tx 10b) resulting from the replacement to the downstream device 1 enables the downstream device 1 to detect the errors during the 10b8b decoding.

On the other hand, if in step S33, device 0 determines that no error is occurring (No), device 0 avoids the above-described replacement and transmits the data subjected to the 8b10b encoding to the downstream device 1 (step S35). Device 0 thus ends this flow (End).

<3. Effects of the Embodiment>

The configuration and operation according to the first embodiment exert at least an effect (1).

(1) Errors in transfer data can be recognized to prevent the data from being corrupted.

As shown in FIG. 1 described above, the present example is applied to the system in which a plurality of transceiver devices following the host apparatus and including the first transceiver device (device 0) and the second transceiver device (device 1) are sequentially connected together in the form of a ring. If errors occur on the transmission path during a data transfer operation in which the upstream device (device 0) serves as a relay station, the upstream device (device 0) replaces the erroneous parts in the transmit data destined for the downstream device (device 1) with unassigned data and transmits the resultant data to the downstream device (device 1) (S34).

For example, as shown in FIG. 8 described above, if errors are occurring, then during the 8b10b encoding & error injection process, the controller 12 replaces the erroneous parts 0xFB and 0xF0 with 0x010, an unregistered pattern (which is not associated with both of D-symbol and K-symbol).

Thus, in the present example, during the 8b10b encoding by the upstream device (device 0) serving as a relay station, the error parts of the transferred data strings are replaced with the pattern (0x010) originally not contained in the 8b10b conversion table to allow the error information to be communicated to the downstream device (device 1).

Hence, in subjecting the transferred data strings to the 10b8b decoding, the succeeding downstream device (device 1) can recognize the parts replaced with the unregistered pattern (0x010) to detect the errors.

As described above, in the present example, even if transferred data is garbled in the transmission path between the host and the upstream device (device 0) by noise or the like with a resulting failure to subject the corresponding parts to the 10b8b decoding, the downstream device (device 1) can recognize the erroneous parts.

When the erroneous parts of the transmitted data cannot be recognized, the downstream device (device 1) is more likely to mistakenly recognize and accept the data as correct data. As a result, the data written to the device by the host may be corrupted.

Hence, the present embodiment has the advantage of allowing the erroneous parts of the transfer data to be recognized to prevent the data from being corrupted.

The first embodiment utilizes the single unregistered pattern (0x010) for all the errors. However, of course, a plurality of unregistered patterns may be prepared so that any of the patterns can be utilized.

### Second Embodiment

Now, a second embodiment will be described with reference to FIG. 10 to FIG. 12. The second embodiment relates to an example in which an erroneous part is replaced with a K-symbol unused for the standard. Detailed descriptions overlapping those given above are omitted.

<K-Symbols>

First, K-symbols will be described with reference to FIG. 10.

As shown in FIG. 10, K-symbols allow any of excess 10-bit patterns resulting from the expression of 8-bit information in 10 bits to be utilized as control codes. The illustrated K-symbols, also used for the UHS-II standard as control codes, are taken as an example.

For example, K-symbol (K28.0) in FIG. 10 has a symbol name SDB, functions to start a data burst (Start of Data Burst), and has a value of 0x1C. Such K-symbols as shown in FIG. 10 are similarly defined.

Here, among the K-symbols shown in FIG. 10, for example, K28.2 (Value: 0x5C), K28.4 (Value: 0x9c), K28.7 (Value: 0xFC), and K30.7 (Value: 0xFE) are unused K-symbols.

The present example is different from the above-described first embodiment in that an erroneous part is replaced with an unused K-symbols such as K28.4 (Value: 0x9c), as described below in detail.

<Data Transfer Operation>

In the present example, the K-symbol unused for the UHS-II standard is embedded in an erroneous part to allow the succeeding node to detect the errors.

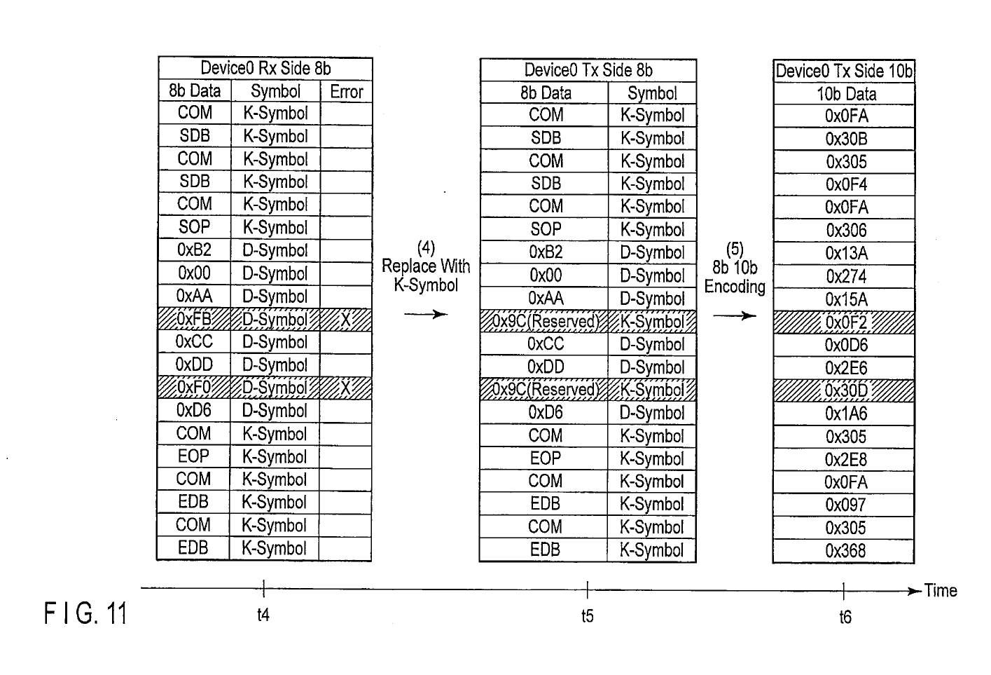

First, the data transfer operation will be described with reference to FIG. 11. The operation performed before the occurrence of errors is similar to that in the above-described embodiment and will thus not be described in detail. FIG. 11 corresponds to an operation after times t1 to t4 shown in FIG. 6 and FIG. 7.

As shown at time t4 in FIG. 11, before the 8b10b encoding (labeled with (5) in FIG. 11), the upstream device 0, serving as a relay station and having received data strings (device 0 Rx side 8b) from the host, replaces erroneous D-symbols with the K-symbol unused for the standard (in the present embodiment, the K-symbol for 0x9C) (labeled with (4) in FIG. 11).

Subsequently, the upstream device 0 carries out similar 8b10b encoding on the resulting data (labeled with (5) in FIG. 11) and transfers the data to the succeeding device 1.

<Data Transfer Flow>

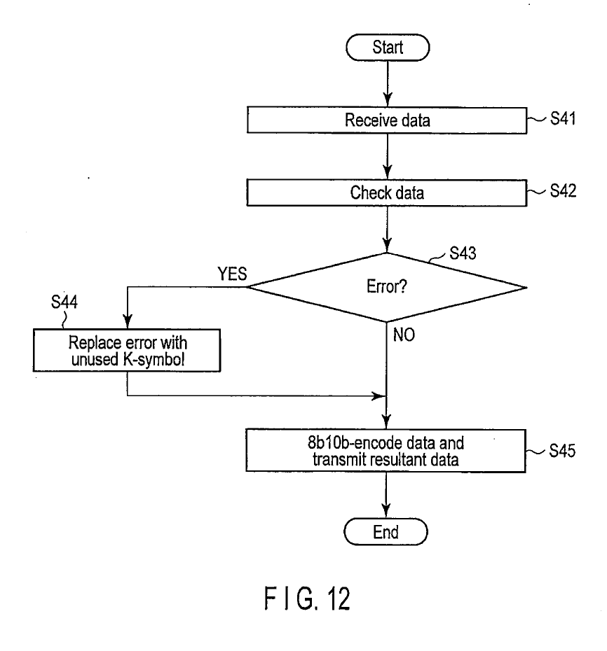

A data transfer flow in the present example is as shown in FIG. 12.

As shown in FIG. 12, the present example is different from the above-described first embodiment in that if in step S43, device 0 determines that errors are occurring (Yes), then in step S44, device 0 replaces each of the D-symbols corresponding to the erroneous parts with the unused K-symbol (control code). For example, as shown at time t5 in FIG. 11 described above, if errors are occurring, each of the D-symbols corresponding to the erroneous parts 0xFB and 0xF0 is replaced with the unused K-symbol (control code).

Subsequently, in step S45, similar 8b10b encoding is carried out on the data resulting from the replacement, and the data is then transferred to the succeeding device 1 (End). Thus, as shown at time t6 in FIG. 11 described above, the 8b10b encoding changes the erroneous parts of the data strings to 0x0F2 and 0x30D to enable the succeeding downstream device 1 to detect the errors during the 10b8b decoding.

This is because the succeeding downstream device 1 discovers the K-symbol undefined for the standard at the originally erroneous parts and can thus determine the corresponding data not to be normal.

<Effects of the Embodiment>

The second embodiment exerts at least an effect similar to the effect (1) described above.

The present example is different from the above-described first embodiment in that if the device determines that errors are occurring (Yes), the device replaces each of the D-symbols corresponding to the erroneous parts with the unused K-symbol (control code). For example, as shown at time t2 in FIG. 11 described above, if errors are occurring, each of the erroneous data 0xFB and 0xF0 is replaced with the unused K-symbol (0x9c).

The erroneous data is thus replaced with the unused K-symbol to allow the downstream device to be notified of the presence of the errors.

### Third Embodiment

### CRC

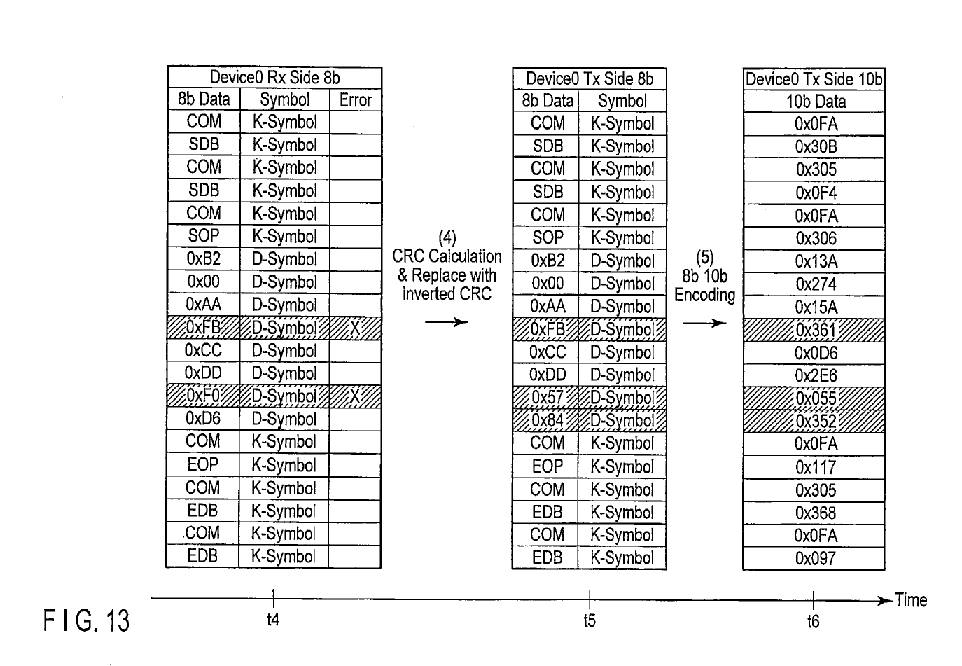

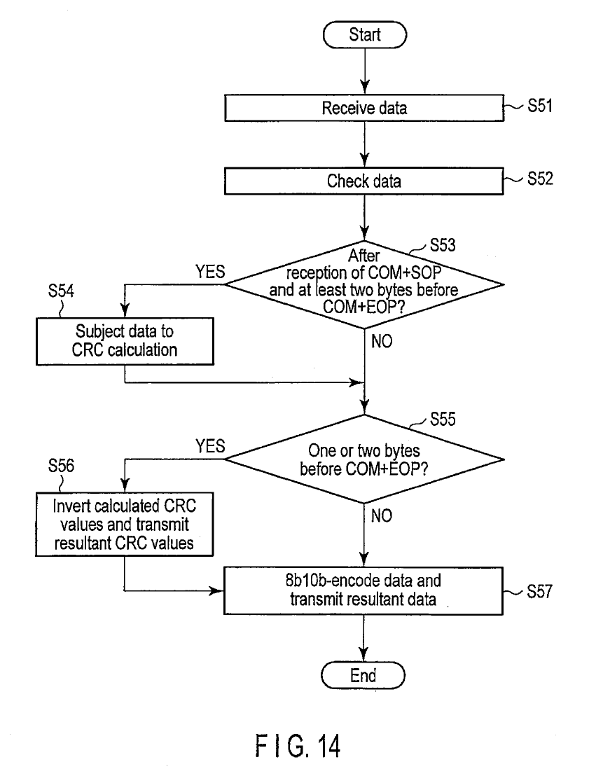

Now, a third embodiment will be described with reference to FIG. 13 and FIG. 14. The present embodiment relates to error detection for CRC. Detailed descriptions overlapping those given above are omitted.

<Data Transfer Operation>

Unlike the above-described first and second embodiments that reduce the latency during data relay, the present embodiment relates to an example in which during data relay, CRC is carried out to detect errors.

Thus, in the present example, as in the case of reception, a CRC calculation is carried out on receive data during relay for a data transfer. The present example is different from the first and second embodiments in that an old CRC value is replaced with a newly calculated CRC value with at least one bit value changed, with the resultant CRC value transmitted to the downstream device.

Thus, CRC carried out by the succeeding downstream device results in an error, preventing erroneous reception.

The CRC calculation is carried out on the data in a packet, and a COM+SOP control code indicative of the head of the packet, data, the CRC value, and COM+EOP, which is indicative of the end of the packet are transmitted in this order.

For example, in the present example, more specifically, processing is carried out as shown in FIG. 13. FIG. 13 corresponds to an operation performed after times t1 to t4 shown in FIG. 6 and FIG. 7.

First, as shown at times t4 to t6 in FIG. 13, the garbled erroneous data 0xFB is considered to be normal, and a CRC recalculation is carried out for the garbled erroneous data 0xFB, as if the data is correct data. In this regard, parts for CRC originally present in the packet (in the present example, the 2-byte data preceding COM+EOP 0xF0 and 0xD6) are excluded from the targets for the calculation in the present example.

Thus, as in the processing (labeled with (4) in FIG. 13) shown in FIG. 13, a CRC recalculation inverts the values of the relevant parts and replaces the old values with the calculated values. CRC may invert at least one bit, but in the present embodiment, all the bits are inverted.

Subsequently, similar 8b10b encoding is carried out (labeled with (5) in FIG. 13), and the data obtained is then transferred to the succeeding downstream device.

<Data Transfer Flow>

A data transfer flow in the present example is as shown in FIG. 14.

As shown in FIG. 14, in the present example, first, in step S53, the upstream device 0 determines whether or not checked transfer data has been obtained after reception of COM+SOP and at least two bytes before COM+EOP. If the result of the determination in step S53 is negative (No), the flow proceeds to step S55.

If the result of the determination is affirmative (Yes), then unlike in the above-described embodiments, device 0 carries out a normal CRC calculation on erroneous parts in step S54.

Subsequently, in step S55, device 0 determines whether or not the data is located one or two bytes before COP+EOP.

Subsequently, if the result of the determination in step S55 is affirmative (Yes), then in step S56, device 0 inverts the calculated CRC values. For example, as shown in FIG. 13, a CRC recalculation inverts the values of the relevant parts and replaces the old values with the calculated values. Subsequently, the flow proceeds to step S57.

If the result of the determination in step S55 is negative (No), device 0 proceeds to step S57 without carrying out the processing in step S56. Device 0 carries out 8b10b encoding on the data and transfers the resulting data to the succeeding downstream device 1 (End).

<Effects of the Embodiment>

The third embodiment exerts at least an effect similar to the effect (1) described above.

Moreover, in the present example, during data relay, CRC is carried out to detect errors.

For example, if the result of the determination in step S55 is affirmative (Yes), then in step S56, the calculated CRC values are inverted. As shown in FIG. 13, a CRC recalculation inverts the values of the relevant parts and replaces the old values with the calculated values.

This operation allows the transmitted data to cause a CRC error in the downstream device 1. This indirectly informs device 1 that the error has occurred in the transmission path between the host and device 0. Thus, erroneous reception can be prevented.

### Fourth Embodiment

### An Example with Replacement with a Control Code Used

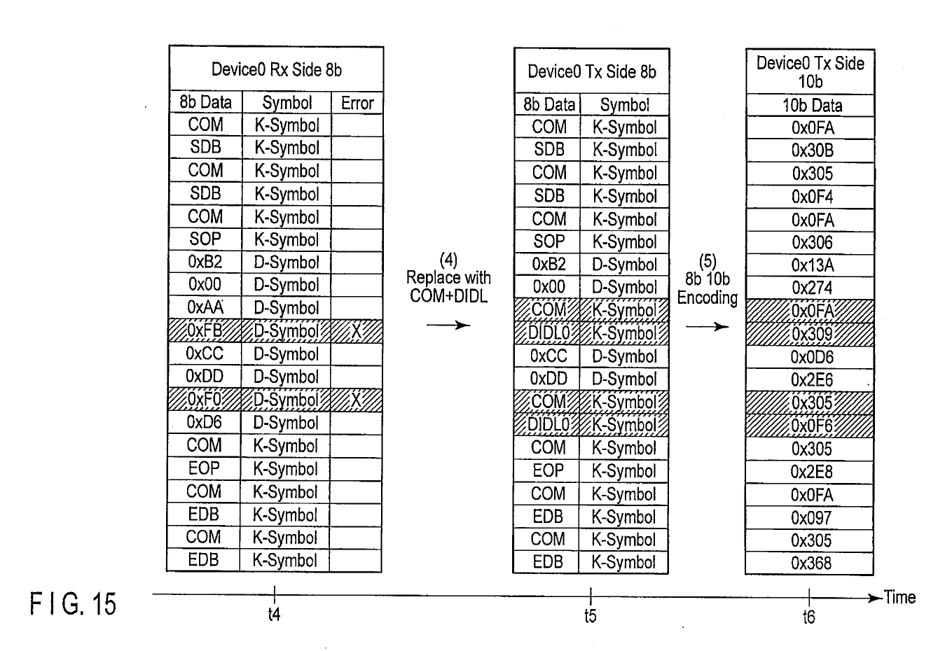

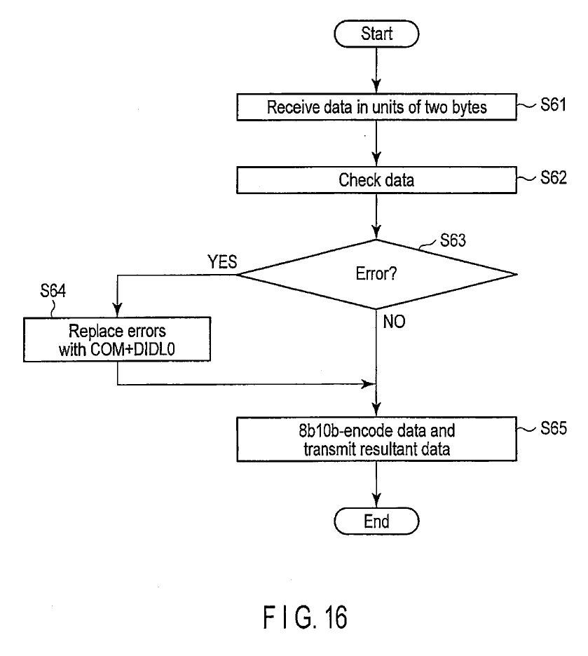

Now, a fourth embodiment will be described with reference to FIG. 15 and FIG. 16. FIG. 15 corresponds to an operation performed after times t1 to t4 shown in FIG. 6 and FIG. 7. The present embodiment relates to an example in which erroneous data is replaced with a control code used, to allow the error to be detected. Detailed descriptions overlapping those given above are omitted.

<Data Transfer Operation>

The present example relates to a method using a control code utilized for the standard.

As described in the second embodiment, the UHS-II standard defines K-symbols, and a set of a certain K-symbol and any data forms a control code with a certain meaning. More specifically, a set of the K-symbol COM and a K-symbol different from COM or a D-symbol forms a control code with a certain meaning. Examples of the set include COM+LIDL0 (K-symbol), COM+LIDL1 (D-symbol), COM+DIDL0 (K-symbol), and COM+DIDL1 (D-symbol). These are control codes only indicative of an idle state.

Thus, in the present example, the control code only indicative of the idle state is embedded in erroneous parts to allow the succeeding downstream device (device 1) to detect the errors. The operation performed before the occurrence of the errors is similar to that in the first embodiment.

As shown at time t4 in FIG. 15, during the processing labeled with (4), device 0 checks every two bytes to determine whether any error is occurring. Then, device 0 replaces the erroneous parts (0xFB and 0xF0) with COM+DIDL0, which is indicative of the idle state during a data burst transfer.

Subsequently, device 0 carries out similar 8b10b encoding (labeled (5) in FIG. 15) and transfers the resulting data to the succeeding downstream device 1.

<Data Transfer Flow>

A data transfer flow in the present example is as shown in FIG. 16.

As shown in FIG. 16, in the present example, if in step S63, device 0 determines that errors are occurring (Yes), then in step S64, device 0 replaces the relevant parts with COM+DIDL0, which is indicative of the idle state in a data burst transfer. For example, as shown in FIG. 15, device 0 replaces the erroneous parts (0xFB and 0xF0) with COM+DIDL0.

Subsequently, device 0 similarly carries out the 8b10b encoding and transfers the resulting data to the succeeding downstream device 1 (End).

Thus, in the present example, COM+DIDL0, which is indicative of the idle state, is present in the originally erroneous parts. COM+DIDL0 is normally not present in any data packet. In other words, a data structure with COM+DIDL0 present in a data packet is not defined in the standard. Thus, the succeeding downstream device can determine packets mixed with COM+DIDL0 not to be normal. The present description selects COM+DIDL0 as a code for replacement which is indicative of the idle state. However, another code indicative of the idle state may be used, that is, COM+LIDL0, COM+LIDL1, or COM+DIDL1.

<Effects of the Embodiment>

The fourth embodiment exerts at least an effect similar to the effect (1) described above.

Moreover, in the present example, if in step S63, the device determines that errors are occurring (Yes), the device replaces the relevant parts with COM+DIDL0, which is indicative of the idle state during a data burst transfer (step S64).

Thus, if errors occur, the downstream device can be notified of the presence of the errors by converting the relevant data into a structure different from those defined in the standard.

The present example can be applied as necessary.

[Modifications]

In the above-described referential example and embodiments, the host apparatus and two devices (device 0 and device 1) connected together in the form of a ring are taken as an example. However, the embodiments are not limited to this configuration.

For example, the present embodiments is also applicable to the host apparatus and at three or more devices (device 0, device 1, device 2, . . . , device N) connected together in the form of a ring. In this case, the data relay station is any device other than the destination station.

Furthermore, the data transfer from the host apparatus to the device has been described. However, the present embodiments are also applicable to a data transfer from the device to the host apparatus provided that a relay station is present between the device and the host apparatus. That is, in the above-described embodiments, device 0 described as the upstream device may be replaced with device 1 in FIG. 1, whereas device 1 described as the downstream device may be replaced with the host. If the data is destined for the host and an error occurs between device 0 and device 1, device 1 may carry out a data conversion by the method according to any of the first to fourth embodiments. Alternatively, the present embodiments may be also applicable to a data transfer from the device to another device with a relay station (transceiver device and/or host device) interposed therebetween.

Additionally, the present embodiments are not limited to the ring connection but are similarly applicable to, for example, a multiplex transmission system in which the host is connected in series with a plurality of devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A system including a plurality of ring-connected devices comprising:
a first device; and
a second device connected to receive a signal from the first device,
wherein when the first device is a data relay station and receives data containing an error, the first device replaces a part of the data with internally generated data and transmits the resultant data to the second device.

2. The system according to claim 1, wherein the data internally generated by the first device is one of
a data pattern unused for 8b10b encoding,
a K-symbol unused for a standard, and
a control code indicative of an idle state.

3. The system according to claim 1, wherein the first device performs 10b8b encoding and error detection on the received data, replaces data bits in which the error has been detected with a data pattern unused for the 8b10b encoding, and transmits the data resulting from the replacement to the second device, and
the second device recognizes the error contained in the received data based on a presence of the data pattern unused for the 8b10b encoding.

4. The system according to claim 1, wherein the first device performs 10b8b encoding and error detection on the received data, replaces data bits in which the error has been detected with a K-symbol unused for a standard with which the system complies, and transmits the data resulting from the replacement to the second device, and
the second device recognizes the error contained in the received data based on a presence of the K-symbol unused for the standard.

5. The system according to claim 4, wherein the standard is a UHS-II standard.

6. The system according to claim 1, wherein the first device performs 10b8b encoding and error detection on the received data, replaces data bits in which the error has been detected with a symbol indicative of an idle state, and transmits the data resulting from the replacement to the second device, and
the second device recognizes the error contained in the received data based on a presence of the symbol indicative of the idle state.

7. The system according to claim 6, wherein the symbol indicative of the idle state is a combination of a particular K-symbol and any K-symbol or a D-symbol.

8. The system according to claim 1, wherein the first device performs a CRC calculation on the data, changes the calculated CRC value, and transmits the changed CRC value to the second device, and
the second device performs CRC on the received data to recognize the error contained in the data.

9. The system according to claim 1, wherein the ring-connected devices include a plurality of transceiver devices and a host apparatus configured to manage the transceiver devices, and
the first and second devices are the transceiver devices.

10. The system according to claim 1, wherein the ring-connected devices include a plurality of transceiver devices and a host apparatus configured to manage the transceiver devices, and
the first device is the transceiver device, and the second device is the host apparatus.

11. A device which is connected to other device in series comprising:
a semiconductor memory capable of holding data in a nonvolatile manner;
a controller configured to control operation of the semiconductor memory and to transmit and receive a signal to and from an exterior,
wherein when the controller is a data relay station and receives data containing an error, the controller replaces a part of the data with internally generated data and transmits the resultant data to the other device.

12. The device according to claim 11, wherein the data internally generated by the controller is one of
a data pattern unused for 8b10b encoding,
a K-symbol unused for a standard, and
a control code indicative of an idle state.

13. The device according to claim 11, wherein the controller performs 10b8b encoding and error detection on the received data,
replaces data bits in which the error has been detected with a data pattern unused for the 8b10b encoding, and
transmits the data to the other device with the data pattern as an indicator for a presence of the error.

14. The device according to claim 11, wherein the controller performs 10b8b encoding and error detection on the received data,
replaces data bits in which the error has been detected with a K-symbol unused for a standard with which the device complies, and
transmits the data to the other device with the data pattern as an indicator for a presence of the error.

15. The device according to claim 14, wherein the standard is a UHS-II standard.

16. The device according to claim 11, wherein the controller performs 10b8b encoding and error detection on the received data,
replaces data bits in which the error has been detected with a symbol indicative of an idle state, and
transmits the data to the other device with the symbol indicative of the idle state as an indicator for a presence of the error.

17. The device according to claim 16, wherein the symbol indicative of the idle state is a combination of a particular K-symbol and any K-symbol or a D-symbol.

18. The device according to claim 11, wherein the controller performs a CRC calculation on the data, changes the calculated CRC value, and transmits the changed CRC value to the other device.
